(19) United States
(12) Patent Application Publication
(10) Pub. No.: US 2023/0089289 A1
(43) Pub. Date: Mar. 23, 2023

(54) ELECTRIC CIRCUIT STRUCTURE FOR AN ALTERNATING HEATING AND CAPACITIVE MEASURING MODE, AND ASSOCIATED METHOD

(71) Applicant: Preh GmbH, Bad Neustadt a.d. Saale (DE)

(72) Inventors: Manfred SCHNEIDER, Oberthulba (DE); Georg DANIEL, Bad Neustadt a.d. Saale (DE); Friedrich WIELAND, Bad Neustadt a.d. Saale (DE)

(73) Assignee: Preh GmbH, Bad Neustadt a.d. Saale (DE)

(21) Appl. No.: 17/933,646

(22) Filed: Sep. 20, 2022

(30) Foreign Application Priority Data
Sep. 22, 2021 (DE) 102021124564.8

(51) Int. Cl. B62D 1/06; G01V 3/08; G01D 5/24; H05B 1/02; H05B 3/06

(52) U.S. Cl. CPC B62D 1/06; G01V 3/088; G01D 5/24; H05B 1/0236; H05B 3/06

(57) ABSTRACT

A circuit structure and a method for carrying out an alternating heating and capacitive measuring mode by a common heating wire is presented. The method includes carrying out a heating mode, during which from a switching by a control circuit switching elements are in a conducting state, the switching elements are connected in series, so that the heating wire is supplied with a heating current from two different heating potentials; triggering a change into a detecting mode by the control circuit, so that the switching elements switch from the heating mode into a measuring mode, during which the switching elements are in a blocking state, so that the two different heating potentials are each interrupted several times; carrying out the measuring mode, in which the capacitance of the heating wire relative to a reference potential is determined by a detecting circuit by applying to the heating wire an alternating voltage.

In vehicles, the steering wheel and driver's seat of a motor vehicle are generally equipped with an electric heating system as a comfort function; for this purpose, a heating wire is routed through the grip portion, particularly the steering wheel rim of the steering wheel, and the seat cushion and the backrest cushion of the seat. Because of safety considerations, but also in order to realize additional comfort functions, there is a demand for a capability of also carrying out a detection of a touch or at least an approach, such as the so-called hands-on detection, the purpose of which is to monitor the gripping of the steering wheel rim, or the driver/passenger recognition, the purpose of which is, for example, the seating position-specific activation or deactivation of particular comfort functions. It therefore makes sense to use the heating wire, during a non-heating phase, as an electrode for a capacitive approach detection in the so-called measuring mode. Since the heating mode is usually carried out with a pulse-width modulated heating current, there are phases in which no heating current is applied and which are used for the measuring mode. In order to avoid, during the measuring mode, interferences from “all sides”, i.e. from all poles of the heating voltage providing the heating current, into the heating wire as a capacitive electrode and a reference electrode or the mass potential, it is known from DE 11 2014 002 044 T5, for example, to separate in the measuring mode the heating wire on all poles from the poles providing the different heating potentials, using field effect transistors. Switching means, particularly field effect transistors, have parasitic capacitances that may cause disturbances when determining the actual measuring capacitance. US 2010/0038351 A1 proposes that the insulating effect of the blocking switching means be supported in the measuring mode by additional impedances, in particular diodes, wherein a shielding signal may additionally be applied to the connecting line between the diodes and the switching means. Such a solution is disadvantageous in that the additional impedances, particularly the diodes, affect the heating current, in particular have ohmic losses, and thus, the electrical heating voltage cannot be optimally converted into thermal heating power (Joule heat) released by the heating wire.

Against this background, it is the object of the present disclosure to provide a circuit structure for an alternating heating and capacitive measuring mode, in which the heating current can be used more efficiently for heating in the heating mode, and at the same time, the reliability of the capacitive approach measurement in the measuring mode is at least maintained or improved.

This object is achieved by a circuit structure of claim 1. Other features, embodiments, properties and advantages are apparent from the dependent claims, the description and the Figures. A method for carrying out an alternating heating and capacitive measuring mode by means of a common heating wire according to the present disclosure, as well as the use of the circuit assembly according to the present disclosure, are each the subject matter of the co-ordinated independent claims.

The present disclosure relates to an electric circuit structure for an alternating heating and capacitive measuring mode using a common heating wire, wherein in the heating mode, the heating wire, which is a resistance wire, for example, such as a nickel-chrome wire, is flooded with an electric heating current supplied by two poles at two different heating potentials, wherein a heating voltage drops on the heating wire. The circuit assembly has a pair of first switching elements and a pair of second switching elements. Preferably, the first switching elements are formed by a transistor, more preferably in each case a field effect transistor, most preferably a metal-oxide-semiconductor field-effect transistor (MOS-FET). More preferably, the first and second switching elements are realized by a transistor, more preferably in each case a field effect transistor, most preferably a metal-oxide-semiconductor field-effect transistor (MOS-FET). The heating wire is in this case connected to the first and second switching elements in such a way that in the heating mode, during which the first and second switching elements, and thus simultaneously, are in a conducting state, the first and second switching elements and the heating wire are connected in series. In this case, the heating wire is conductively connected, in each case via a first switching element and a second switching element connected via a conductor portion to the first switching element, to one of two different heating potentials, e.g. vehicle ground on the one hand and the positive battery potential on the other. Because the first and second switching elements are connected through in the heating mode, the heating wire is flooded with the heating current. If at least one switching element of the first and second switching elements is in the non-conducting or blocking state, no heating current is present. By periodically switching and changing the duration of the respective heating mode, e.g. by controlling at least one or all switching elements by means of a pulse-width modulated signal, the heating power of the heating wire can thus be adjusted.

According to the present disclosure, there is also provided a detecting circuit, in order to determine, in a measuring mode taking place outside of the time frame of the heating mode, the capacitance of the heating wire relative to a reference potential, e.g. that of the reference electrode or the vehicle ground, by applying to the heating wire an alternating voltage from an AC voltage source. Based on a change in this capacitance, the approach of a vehicle occupant, or at least the approach of a hand of the vehicle occupant, can be detected, for example. Various methods for determining a capacitance of this kind are known. According to the present disclosure, such methods are used herein in which the capacitance can be reliably detected by applying an alternating voltage to the heating wire as a transmitting electrode. Amplitude-modulated detecting circuits supply the capacitor, which is formed by the heating wire and which is to be subjected to measuring, with a high-frequency alternating current (e.g. 20 kHz) and detect the resulting reactive current.

In frequency-modulated detecting circuits, the capacitor to be subjected to measuring is connected to an inductance to form a resonant circuit as a component of an LC oscillator, whose frequency is measured by being compared with a reference. In another variant of the frequency-modulated detecting circuit, the measuring capacitor is a component of an astable multivibrator. Preferably, the detecting circuit is designed for measuring in the measuring mode a current curve between the heating conductor and the AC voltage source resulting from the application of the alternating voltage, in order to determine therefrom the capacitance, based on a phase shift between the alternating voltage and the current curve. For example, the current curve is measured based on a voltage drop on a shunt resistor (shunt) while amplifying the signal by means of a measuring amplifier.

According to the present disclosure, there is also provided a control circuit for switching the first switching elements and second switching elements from the heating mode into the measuring mode, during which the first switching elements and the second switching elements are in a blocking state, so that the two connections of the heating wire with the two different heating potentials, which are electrically conducting in the heating mode, are each interrupted several times in the measuring mode.

The multiple interruption with regard to the two heating potentials is advantageous in that, in addition to the particularly effective capacitive decoupling of the heating wire with respect to the heating potentials and the reduction of the parasitic capacitances on the connection with the heating potentials, which is interrupted several times and in which now the switching elements are to be considered as series-connected capacitive impedances, a detecting circuit using an alternating voltage can also be used in an improved manner, because the first switching elements, as opposed to the non-symmetrically connected diodes of the prior art, for example, separate symmetrically, and this separation has an effect on both current directions of the alternating current generated in the measuring mode, which facilitates and improves the determination of the capacitance by means of alternating voltage, but particularly the preferred path via the detection of the phase shift. Preferably, the circuit structure is designed such that the heating mode and the measuring mode are operated in an alternating manner. For example, the control circuit is configured for generating a pulse-width modulated control signal for the first and/or second switching elements. Moreover, a microcontroller, for example, is provided in order to vary the duty cycle of the pulse-width modulated control signal in accordance with a desired and/or predetermined heating power.

According to a preferred embodiment of the circuit structure according to the present disclosure, there is also provided a shielding circuit, which is configured to apply to at least the conductor portions between, in each case, the first and the second switching element the alternating voltage from the AC voltage source during the measuring mode. In this case, the repeated usage of the term alternating voltage is supposed to refer to the fact that the alternating voltage present on the heating wire in the measuring mode and the alternating voltage present on the conductor portions substantially match each other with respect to amplitude, frequency and phase in order to obtain an optimum shielding effect.

According to a preferred embodiment, at least the first switching elements are transistors, in particular field effect transistors, and the shielding circuit is designed such that in the measuring mode, the alternating voltage is applied in each case to a control terminal of the associated transistor, such as base or gate, in order to obtain a particularly effective shielding effect. In this case, the alternating voltage and/or the first switching elements are designed such that a switching process of the first switching elements in the measuring mode is excluded.

According to a preferred embodiment, the detecting circuit is supplemented with a compensating circuit for compensating a temperature-dependent blocking behavior of the first switching elements, particularly if they are configured as field effect transistors and a temperature-dependent reactive current cannot be suppressed completely. In order to compensate this, the compensating circuit is configured, for example, to change the operating point of the measuring amplifier measuring the curve of the alternating current in a temperature-dependent manner and so as to counteract the change of the blocking behavior. For this purpose, the compensating circuit has, for example, a microcontroller-controlled reference circuit forming an R-2R network.

Furthermore, the present disclosure relates to a use of the circuit structure of one of the above described embodiments in a motor vehicle, wherein the heating wire is integrated into a steering wheel of the motor vehicle, e.g. into a steering wheel rim of the steering wheel.

The present disclosure further relates to a method for carrying out an alternating heating and capacitive measuring mode by means of a common heating wire, comprising the following steps.

In a heating mode, a pair of first switching elements and a pair of second switching element are switched to a conducting state by a control circuit. During this heating mode, the first switching elements and the second switching elements and the heating wire are connected in series. Further, in the heating mode, the heating wire is conductively connected, in each case via a first switching element and a second switching element connected via a conductor portion to the first switching element, to one of two different heating potentials, so that the heating wire is supplied with a heating current due to the different heating potentials.

In a subsequent step, a change into a detecting mode is triggered by the control circuit, so that the first switching elements and the second switching elements switch from the heating mode into a measuring mode, during which the first switching elements and the second switching elements are in a blocking state. Thus, the two connections of the heating wire with the two different heating potentials, which are electrically conducting in the heating mode, are each interrupted several times in the measuring mode. During the measuring mode, the capacitance of the heating wire relative to a reference potential is determined by a detecting circuit by applying to the heating wire an alternating voltage from an AC voltage source. Then, a switchover from the measuring mode into the heating mode preferably takes place; more preferably, the heating mode and the measuring mode are operated in an alternating manner.

According to a preferred embodiment of the method according to the present disclosure, the alternating voltage from the AC voltage source is applied by a shielding circuit to the conductor portions during the measuring mode. In this case, the usage of the term alternating voltage is supposed to refer to the fact that the alternating voltage present on the heating wire in the measuring mode and the alternating voltage present on the conductor portions substantially match each other with respect to amplitude, frequency and phase in order to obtain an optimum shielding effect.

According to a preferred embodiment, at least the first switching elements are realized by transistors, in particular field effect transistors, wherein, because of the design of the shielding circuit, in the measuring mode, the alternating voltage is applied in each case to a control terminal of the associated transistor, such as base or gate, in order to obtain a particularly effective shielding effect. In this case, the alternating voltage and/or the first switching elements are designed such that a switching process of the first switching elements in the measuring mode is excluded.

According to a preferred embodiment of the method, a current curve between the heating conductor and the AC voltage source resulting from the application of the alternating voltage is measured in the measuring mode by the detecting circuit, in order to determine therefrom the capacitance based on a phase shift between the alternating voltage and the current curve.

According to a preferred embodiment of the method, a temperature-dependent blocking behavior of the first switching elements is compensated during the detection process, particularly if they are configured as field effect transistors and a temperature-dependent reactive current cannot be suppressed completely. In order to compensate this, the detecting circuit is supplemented with a compensating circuit, which changes the operating point of the measuring amplifier measuring the curve of the alternating current in a temperature-dependent manner and so as to counteract the change of the blocking behavior. For this purpose, the compensating circuit has, for example, a microcontroller-controlled reference circuit forming an R-2R network.

The various disclosed embodiments are explained further with reference to the following Figures. The Figures are to be understood only as examples and merely represent a preferred embodiment. In the Figures:

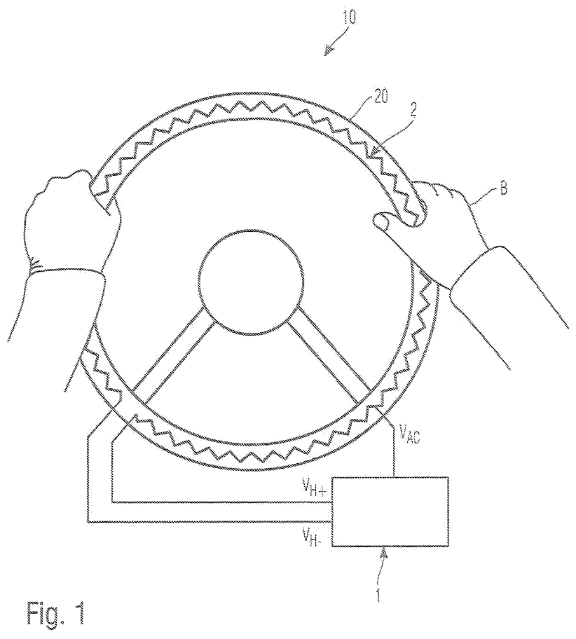

FIG. 1 shows a schematic top view of a steering wheel with a heating wire, which is integrated therein and belongs to the circuit structure according to an embodiment;

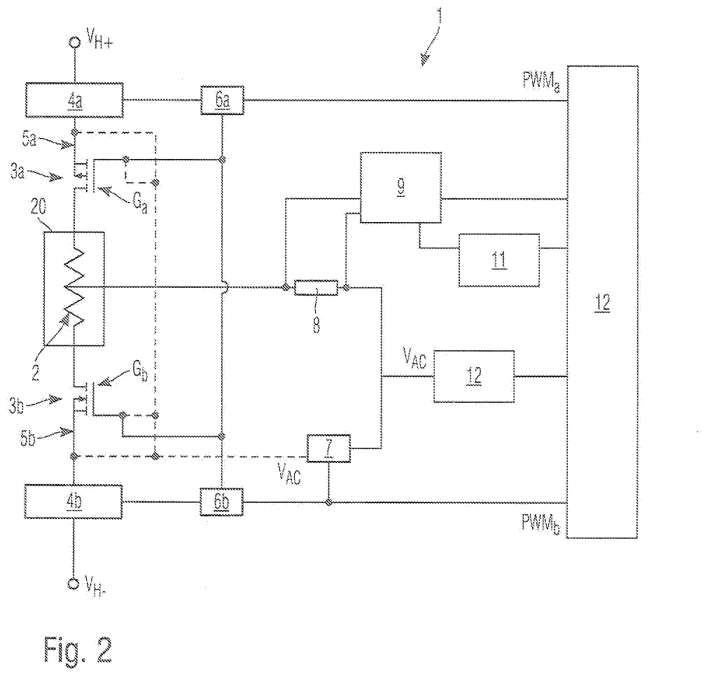

FIG. 2 shows a schematic view of the circuit structure according to an embodiment.

FIG. 1 shows the use of the circuit structure 1 according to the embodiment in a steering wheel 10 of a motor vehicle that is not depicted. A heating wire 2, which is a resistance wire, for example, such as a nickel-chrome wire, is integrated into the grip portion 20, in this case the steering wheel rim, of the steering wheel in order to, on the one hand, heat in a heating mode of the circuit structure 1 the grip portion 20 for a vehicle occupant B gripping the steering wheel 10, and, on the other hand, carry out a capacitive detection of a touch or approach with regard to the hand of the vehicle occupant B touching the grip portion 20 or approaching the grip portion 20. Because of safety considerations, but also in order to realize additional comfort functions, this capacitive detection of a touch or at least an approach is provided for performing the so-called hands-on detection, for example, the purpose of which is to monitor the gripping of the steering wheel rim, or performing the driver/passenger recognition, the purpose of which is, for example, the seating position-specific activation or deactivation of particular comfort functions. As indicated in FIG. 1, the heating wire 2 is supplied in the heating mode with a heating current from the different heating potentials V_{H+}, V_{H-}. For example, V_{H-} is at vehicle ground potential. In the detecting mode, an alternating voltage V_{AC} is applied by the circuit structure 1 according to the embodiment to the heating wire 2.

FIG. 2 schematically shows the electric circuit structure 1 for an alternating heating and capacitive measuring mode using a common heating wire 2. In this case, the heating wire 2 is flooded in the heating mode with an electric heating current supplied by two poles at the two different heating potentials V_{H+}, V_{H-}, wherein a heating voltage drops on the heating wire 2. For this purpose, the circuit assembly 1 has a pair of first switching elements 3a, 3b and a pair of second switching elements 4a, 4b. Here, the first switching elements 3a, 3b are formed in each case by a field effect transistor, in particular a self-blocking field effect transistor, preferably a metal-oxide-semiconductor field-effect transistor (MOS-FET). The second switching elements 4a, 4b are also realized in each case by a transistor, more preferably in each case a field effect transistor, most preferably a metal-oxide-semiconductor field-effect transistor (MOS-FET). The heating wire 2 is in this case connected to the first switching elements 3a, 3b and the second switching elements 4a, 4b in such a way that in the heating mode, during which the first switching elements 3a, 3b and the second switching elements 4a, 4b, and thus simultaneously, are in a conducting state, the first switching elements 3a, 3b and the second switching elements 4a, 4b and the heating wire 2 are connected in series. In this case, the heating wire 2 is conductively connected, in each case via a first switching element 3a, 3b and a second switching element 4a, 4b connected via a conductor portion 5a, 5b to the first switching element 3a, 3b, to one of the two different heating potentials V_{H+}, V_{H-}. Because the first switching elements 3a, 3b and the second switching elements 4a, 4b are connected through (are conducting) in the heating mode, the heating wire 2 is flooded with the heating current. If at least one switching element of the first switching elements 3a, 3b and second switching elements 4a, 4b is in the non-conducting or blocking state, no heating current is present. By periodically switching and changing the duration of the respective heating mode, e.g. by controlling at least one or all switching elements 3a, 3b; 4a, 4b by means of a pulse-width modulated control signal PWMₐ or PWM_{b} of a microcontroller 12 controlling the control circuit 6a, 6b assigned to the switching elements 3a, 3b; 4a, 4b, the heating power of the heating wire 2 can thus be adjusted.

According to the present disclosure, there is also provided a detecting circuit 9, in order to determine, in a measuring mode taking place outside of the time frame of the heating mode, the capacitance of the heating wire 2 relative to a reference potential, such as vehicle ground, by applying to the heating wire 2 an alternating voltage V_{AC} from an AC voltage source 12, in this case a sine-wave generator controlled by the microcontroller 12. Based on a change in this capacitance, the approach of a vehicle occupant B, or at least the approach of a hand of the vehicle occupant B, can be detected, for example. In this case, the detecting circuit 9 is designed for measuring in the measuring mode a current curve between the heating conductor 2 and the AC voltage source 12 resulting from the application of the alternating voltage V_{AC}, in order to determine therefrom the capacitance, based on a phase shift between the alternating voltage V_{AC} and the current curve. In detail, the current curve is measured based on a voltage drop on a shunt resistor 8 (shunt) while amplifying the signal by means of a measuring amplifier of the detecting circuit, whose measurement result is transmitted to the microcontroller 12.

The switchover from the heating mode into the measuring mode is caused by the control circuit 6a, 6b, during which the first switching elements 3a, 3b and the second switching elements 4a, 4b are in a blocking state, so that the two connections of the heating wire 2 with the two different heating potentials, which are electrically conducting in the heating mode, are each interrupted several times in the measuring mode.

The multiple interruption with regard to the two heating potentials V_{H+}, V_{H-} is advantageous in that, in addition to the particularly effective capacitive decoupling of the heating wire 2 with respect to the heating potentials V_{H+}, V_{H-} and the reduction of the parasitic capacitances on the connection with the heating potentials V_{H+}, V_{H-}, which is interrupted several times and in which now the switching elements 3a, 3b; 4a, 4b are to be considered as series-connected capacitive impedances, a detecting circuit 9 using an alternating voltage V_{AC} for detection can also be used in an improved manner, because the first switching elements 3a, 3b, as opposed, for example, to the non-symmetrically connected diodes of the prior art, separate symmetrically, and this separation has an effect on both current directions of the alternating current generated in the measuring mode, which facilitates and improves the determination of the capacitance by means of alternating voltage V_{AC}, but particularly the preferred path via the detection of the phase shift. Due to the control of the control circuit 6a, 6b by the microcontroller 12 using the pulse-width modulated control signals PWMₐ or PWM_{b}, the circuit structure 1 is designed such that the heating mode and the measuring mode are operated in an alternating manner. In this case, the microcontroller 12 regulates the duty cycle of the pulse-width modulated control signals PWMₐ or PWM_{b} in accordance with a desired and/or predetermined heating power.

In the depicted circuit structure 1 according to the embodiment, there is also provided a shielding circuit 7, which is configured to apply the alternating voltage V_{AC} from the AC voltage source 12 during the measuring mode not only to the conductor portion 5a, 5b between, in each case, the first switching element 3a, 3b and the second switching element 4a, 4b, but also to the control terminals Gₐ, G_{b} of the first switching elements 3a, 3b. In this case, the usage of the term alternating voltage is supposed to refer to the fact that the alternating voltage V_{AC} present on the heating wire 2 in the measuring mode and the alternating voltage V_{AC} present on the conductor portions 5a, 5b substantially match each other with respect to amplitude, frequency and phase in order to obtain an optimum shielding effect.

The detecting circuit 9 is supplemented with a compensating circuit 11 for compensating a temperature-dependent blocking behavior of the first switching elements 3a, 3b, in order to compensate a temperature-dependent reactive current or a temperature-dependent blocking behavior of these first switching elements 3a, 3b. Here, the compensating circuit 11 is provided and configured for changing the operating point of the measuring amplifier measuring the curve of the alternating current of the detecting circuit 9 in a temperature-dependent manner and so as to counteract the change of the blocking behavior. For this purpose, the compensating circuit has, for example, a reference circuit forming an R-2R network, which is connected to the microcontroller 12 for controlling the compensation.

What is claimed is:

1. An electric circuit structure for an alternating heating and capacitive measuring mode, comprising:
a pair of first switching elements and a pair of second switching elements;
a heating wire connected to the first switching elements and the second switching elements in such a manner that in a heating mode, during which the first switching elements and the second switching elements are in a conducting state, the first switching elements, the second switching elements, and the heating wire are connected in series, and the heating wire is conductively connected, in each case via the first switching elements and the second switching elements connected via a conductor portion to the first switching element, to one of two different heating potentials, so that the heating wire is supplied with a heating current;
a detecting circuit in order to determine, in a measuring mode taking place outside of a time frame of the heating mode, a capacitance of the heating wire relative to a reference potential by applying to the heating wire an alternating voltage from an AC voltage source;
a control circuit for switching the first switching elements and second switching elements from the heating mode into the measuring mode, during which the first switching elements and the second switching elements are in a blocking state, so that the two connections of the heating wire with the two different heating potentials, which are electrically conducting in the heating mode, are each interrupted several times in the measuring mode.

2. The electric circuit structure according to claim 1, further comprising a shielding circuit, which is configured to apply to, at least the conductor portions, the alternating voltage from the AC voltage source during the measuring mode.

3. The electric circuit structure according to claim 2, wherein the first switching elements are transistors, and the shielding circuit is configured so that in the measuring mode, the alternating voltage is applied in each case to a control terminal of an associated transistor.

4. The electric circuit structure according to claim 1, wherein the detecting circuit is designed for measuring in the measuring mode a current curve between the heating wire and the AC voltage source resulting from the application of the alternating voltage, in order to determine therefrom the capacitance, based on a phase shift between the alternating voltage and the current curve.

5. The electric circuit structure according to claim 1, wherein the detecting circuit is supplemented with a compensating circuit for compensating a temperature-dependent blocking behavior of the first switching elements.

6. Use of the circuit structure according to claim 1 in a motor vehicle, wherein the heating wire is integrated into a steering wheel of the motor vehicle.

7. A method for carrying out an alternating heating and capacitive measuring mode by means of a common heating wire, comprising the following steps:
carrying out a heating mode, during which, due to a switching by a control circuit, a pair of first switching elements and a pair of second switching elements are in a conducting state, the first switching elements, the second switching elements, and the heating wire are connected in series, and the heating wire is conductively connected, in each case via a first switching element and a second switching element connected via conductor portions to the first switching element, to one of two different heating potentials, so that the heating wire is supplied with a heating current;
triggering a change into a detecting mode by the control circuit, so that the first switching elements and the second switching elements switch from the heating mode into a measuring mode, during which the first switching elements and the second switching elements are in a blocking state, so that the two connections of the heating wire with the two different heating potentials, which are electrically conducting in the heating mode, are each interrupted several times in the measuring mode;
carrying out the measuring mode, in which a capacitance of the heating wire relative to a reference potential is determined by a detecting circuit by applying to the heating wire an alternating voltage from an AC voltage source.

8. The method according to claim 7, wherein the alternating voltage from the AC voltage source is applied by a shielding circuit to the conductor portions during the measuring mode.

9. The method according to claim 7, wherein the first switching elements are transistors, and in the measuring mode, the alternating voltage is applied in each case to a control terminal of the transistors.

10. The method according to claim 9, wherein, in the measuring mode, a current curve between the heating wire and the AC voltage source is measured by the detecting circuit, in order to determine the capacitance based on a phase shift between the alternating voltage and the current curve, wherein the current curve results from the applied alternating voltage.

11. The method according to claim 7, wherein a temperature-dependent blocking behavior of the first switching elements is compensated in the measuring mode.

12. The electric circuit structure according to claim 3, wherein the transistors are field effect transistors.

13. The electric circuit structure according to claim 3, wherein the control terminal of transistors is any one of: a base and a gate.

14. The method according to claim 9, wherein the transistors are field effect transistors.

15. The method according to claim 9, wherein the control terminal of the transistors is any one of: a base and a gate.
